(19) United States
(12) Patent Application Publication
(10) Pub. No.: US 2015/0267305 A1
(43) Pub. Date: Sep. 24, 2015

(54) ETCHANT COMPOSITION AND METHOD FOR MANUFACTURING CIRCUIT PATTERN USING THE SAME

(71) Applicant: Samsung Electro-Mechanics Co., Ltd., Suwon (KR)

(72) Inventors: Jae Hoon CHOI, Suwon (KR); Makoto Dobashi, Suwon (KR)

(73) Assignee: Samsung Electro-Mechanics Co., Ltd., Suwon (KR)

(21) Appl. No.: 14/486,502

(22) Filed: Sep. 15, 2014

(30) Foreign Application Priority Data
Mar. 21, 2014 (KR) 10-2014-0033516

(51) Int. Cl. C23F 1/18; H05K 3/06

(52) U.S. Cl. CPC C23F 1/18; H05K 3/061; H05K 3/067

(57) ABSTRACT

An etchant composition may contain 100 parts by weight of an aqueous etchant containing an oxidant, an acid additive, and water and 5 to 40 parts by weight of an organic solvent having a viscosity lower than that of water. And the organic solvent may have a viscosity of 0.8 cP or less.

### CROSS-REFERENCE TO RELATED APPLICATION

This application claims the benefit of Korean Patent Application No. 10-2014-0033516 filed on Mar. 21, 2014, with the Korean Intellectual Property Office, the disclosure of which is incorporated herein by reference.

### BACKGROUND

The present disclosure relates to an etchant composition and a method for manufacturing a circuit pattern using the same.

A metal pattern formed of various conductive materials, for example, metals such as gold, silver, copper, aluminum, and alloys thereof, or the like, is disposed on a board formed of ceramic, glass, or the like, as an electrode or a wiring material.

In order to form such a metal pattern on a circuit board, first, a metal thin film is formed on the board, a resist pattern having a predetermined pattern is formed on the metal thin film, and then, the metal thin film is etched using the resist pattern as a mask. At the time of etching, an etchant depending on characteristics of each of the metals may be used.

The etching of the metal thin film may be performed by nozzle-spraying the etchant, and in the case in which a particle size of the sprayed etchant is large, side etching in which a side of the formed metal pattern is etched may occur, such that a problem in which a width of the metal pattern is not uniform may occur.

In order to solve this problem in view of equipment, a spraying method using a two-flow nozzle for decreasing a particle size of the etchant sprayed from the nozzle and increasing physical impact pressure has been introduced, but it is difficult to manufacture such equipment, and scales of an equipment body and utility may be increased, such that installation and operation costs may be increased.

### RELATED ART DOCUMENT

### (Patent Document 1) Japanese Patent Laid-Open Publication No. 2002-299326

### SUMMARY

An aspect of the present disclosure may provide an etchant composition and a method for manufacturing a circuit pattern using the same.

According to an aspect of the present disclosure, an etchant composition may contain 100 parts by weight of an aqueous etchant containing an oxidant, an acid additive, and water; and 5 to 40 parts by weight of an organic solvent having a viscosity lower than that of water.

The organic solvent may have a viscosity of 0.8 cP or less.

A concentration of the oxidant contained in the aqueous etchant may be 50 g/L to 200 g/L based on the aqueous etchant.

A concentration of the acid additive contained in the aqueous etchant may be 0.1 mol/L to 5 mol/L based on the aqueous etchant.

The organic solvent may have a boiling point of 70° C. or more.

The organic solvent may include one or more of acetonitrile, nitroethane, methylethylketone, and ethylacetate.

The oxidant may include one or more of copper(II) chloride, copper(II) bromide, copper(II) sulfate, copper(II) hydroxide, copper(II) acetate, iron(II) chloride, iron(II) bromide, iron(II) iodide, iron(II) sulfate, iron(II) nitrate, and iron(II) acetate.

The acid additive may include one or more of sulfuric acid, hydrochloric acid, nitric acid, phosphoric acid, formic acid, acetic acid, maleic acid, benzoic acid, glycolic acid, and sulfonic acid.

The aqueous etchant may further contain one or more of hydrogen peroxide (H₂O₂) and sodium chlorate (NaClO₃).

According to another aspect of the present disclosure, a method for manufacturing a circuit pattern may include: preparing a metal layer; forming a resist layer on one surface of the metal layer; exposing and developing the resist layer to form a resist pattern; nozzle-spraying an etchant on one surface of the metal layer and etching the metal layer to form a metal pattern; and removing the resist pattern, wherein the etchant contains 100 parts by weight of an aqueous etchant containing an oxidant, an acid additive, and water; and 5 to 40 parts by weight of an organic solvent having a viscosity lower than that of water.

The organic solvent may have a viscosity of 0.8 cP or less.

An etching factor of the metal pattern formed by etching the metal layer may be 4 or more.

A concentration of the oxidant contained in the aqueous etchant may be 50 g/L to 200 g/L based on the aqueous etchant.

A concentration of the acid additive contained in the aqueous etchant may be 0.1 mol/L to 5 mol/L based on the aqueous etchant.

The organic solvent may have a boiling point of 70° C. or more.

The organic solvent may include one or more of acetonitrile, nitroethane, methylethylketone, and ethylacetate.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a flowchart showing a method for manufacturing a circuit pattern according to an exemplary embodiment of the present disclosure;

FIGS. 2A through 2F show respective steps in a method for manufacturing a circuit pattern according to an exemplary embodiment of the present disclosure; and

FIG. 3 is a schematic cross-sectional view of a metal pattern illustrating an etching factor.

### DETAILED DESCRIPTION

Hereinafter, embodiments of the present disclosure will be described in detail (with reference to the accompanying drawings). The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

An etchant composition according to an exemplary embodiment of the present disclosure may contain an aqueous etchant; and an organic solvent.

The aqueous etchant may contain an oxidant, an acid additive, and water as a solvent. The water may be deionized water. The water is to form a circuit pattern, and for example, deionized water (resistivity of 18MΩ/cm or more) may be used.

The etchant composition according to an exemplary embodiment of the present disclosure may be used to form a metal pattern manufactured by a method for etching a metal layer containing copper, but is not limited thereto.

For example, the etchant composition according to an exemplary embodiment of the present disclosure may be used in the case of forming a resist pattern on a metal layer and etching the metal layer at a portion on which the resist pattern is not formed to form a metal pattern.

The oxidant may obtain electrons of a metal contained in an etched material to dissolve the etched material. For example, the oxidant may obtain electrons of a copper metal contained in a metal layer formed of copper to etch a copper layer.

The oxidant may include one or more of copper(II) chloride, copper(II) bromide, copper(II) sulfate, copper(II) hydroxide, copper(II) acetate, iron(II) chloride, iron(II) bromide, iron(II) iodide, iron(II) sulfate, iron(II) nitrate, and iron(II) acetate, but is not limited thereto.

According to an exemplary embodiment of the present disclosure, a concentration of the oxidant contained in the aqueous etchant may be 50 g/L to 200 g/L based on the aqueous etchant.

In the case in which the concentration of the oxidant contained in the aqueous etchant is less than 50 g/L, the metal layer containing copper may not be etched, or an etching rate may be slow, and in the case in which the concentration is more than 200 g/L, a viscosity of an etchant may be increased, and the etching rate may be increased, such that it may be difficult to control a process rate.

The acid additive may serve as an auxiliary oxidant for etching a metal layer.

Any acid additive may be used without particular limitations as long as it is generally used, but the acid additive may include one or more of sulfuric acid, hydrochloric acid, nitric acid, phosphoric acid, formic acid, acetic acid, maleic acid, benzoic acid, glycolic acid, and sulfonic acid.

A concentration of the acid additive contained in the aqueous etchant may be preferably 0.1 mol/L to 5 mol/L based on the aqueous etchant. In the case in which the concentration of the acid additive contained in the aqueous etchant is less than 0.1 mol/L, the etching rate of the metal layer may be decreased, such that a defect of etching profile and residues may occur, and in the case in which the concentration is more than 5 mol/L, over-etching may occur, the metal layer or the resist pattern may be subjected to chemical attack.

The organic solvent may have a viscosity lower than that of water (H₂O), and the etchant composition according to an exemplary embodiment of the present disclosure may contain 5 to 40 parts by weight of the organic solvent based on 100 parts by weight of the aqueous etchant.

The etchant composition contains 5 to 40 parts by weight of the organic solvent having a low viscosity based on 100 parts by weight of the aqueous etchant, such that a viscosity and surface tension of the etchant may be decreased, and in the case of spraying the etchant using a nozzle, a particle size of the sprayed etchant may be decreased.

In the case of etching a metal layer on which a resist pattern is formed to form a metal pattern, side etching that the metal layer disposed beneath the resist pattern is partially dissolved may occur. That is, a portion covered by the resist pattern so as not to be removed may be removed by the side etching, such that a width of a circuit pattern may be non-uniformly formed. In the case in which side etching occurs, the circuit pattern may be formed in a shape in which a width thereof is decreased toward an upper portion thereof, and as the circuit pattern becomes fine, an influence of the side etching may be increased.

A ratio of the side etching to etching in a vertical direction may be increased as the particle size of the etchant sprayed from the nozzle is increased.

However, in the case of etchant composition according to an exemplary embodiment of the present disclosure, the particle size of the etchant sprayed from the nozzle may be decreased due to decreases in the viscosity and surface tension of the etchant, thereby decreasing the ratio of the side etching and increasing a ratio of the etching in the vertical direction due to hitting of the etchant in the vertical direction.

The content of the organic solvent may be 5 to 40 parts by weight based on 100 parts by weight of the aqueous etchant. In the case in which the content of the contained organic solvent is less than 5 parts by weight based on 100 parts by weight of the aqueous etchant, a mixing effect of the organic solvent may be insignificant, such that efficiency of decreasing the side etching may not be large, and in the case in which the content of the organic solvent is more than 40 parts by weight based on 100 parts by weight of the aqueous etchant, the etching rate may be decreased, and etching performance may be decreased.

According to an exemplary embodiment of the present disclosure, in order to implement an excellent mixing effect of the organic solvent on the aqueous etchant in the etchant composition, it is preferable that the organic solvent has a viscosity of 0.8 cP or less. In the case in which the organic solvent has a viscosity of 0.8 cP or less, at the time of mixing the organic solvent with the aqueous etchant using water as a solvent, the viscosity and surface tension of the etchant may be effectively decreased.

The etchant composition according to an exemplary embodiment of the present disclosure contains the organic solvent having a viscosity of 0.8 cP or less, such that at the time of etching the metal layer, a ratio of anisotropic etching in the vertical direction may be increased, and high linearity of the formed metal pattern may be implemented. In addition, at the time of etching the metal layer, the side etching may be decreased, such that a metal pattern having a high etching factor may be formed.

A boil point of the organic solvent may be 50° C. or more. In the case in which the boiling point of the organic solvent is less than 50° C., the organic solvent may evaporate during an etching process, such that the viscosity of the etchant may be increased. More preferably, the boil point of the organic solvent may be 70° C. or more.

Any organic solvent may be used without particular limitations as long as it has a viscosity of 0.8 cP or less and a boil point of 70° C. or more. For example, the organic solvent may include one or more of acetonitrile, nitroethane, methylethylketone, and ethylacetate.

Acetonitrile has a viscosity of about 0.37 cP and a boiling point of about 82° C., and nitroethane has a viscosity of about 0.68 cP and a boiling point of about 114° C. Methylethylketone has a viscosity of about 0.43 cP and a boiling point of about 80° C., and ethylacetate has a viscosity of about 0.47 cP and a boiling point of about 77° C.

Among the organic solvent, a solvent having a low viscosity but having a low boiling point is inappropriate for being used as the organic solvent of the present disclosure. Generally, in an etching process of a metal layer using an etchant, an etchant heated to about 40° C. to 50° C. is frequently used in consideration of process efficiency and quality problems. In this case, an organic solvent having a low boiling point evaporates first to thereby change a composition of the etchant. In addition, in the case of using the etchant at room temperature, a solvent having a low boiling point is inappropriate in view of storage stability of the etchant.

The etchant composition may selectively further contain a recycling additive for recycling the used etchant to reuse the recycled etchant.

The recycling additive may serve to increase an oxidation number of the oxidant of which an oxidation number was decreased by obtaining electrons from the metal layer during the etching process of the metal layer again. For example, the recycling additive may include one or more of hydrogen peroxide (H₂O₂) and sodium chlorate (NaClO₃), but is not limited thereto.

In the case in which the etchant composition contains the recycling additive, a concentration of the recycling additive may be 0.01 g/L to 5 g/L based on the aqueous etchant.

The etchant composition may selectively further contain an azole compound.

Since the azole compound has a nitrogen atom capable of providing an electron in a molecule, the azole compound may be weakly coordinated to a surface of a metal. Therefore, the azole compound may suppress the side etching while existing at aside of the formed circuit pattern to promote the anisotropic etching, thereby further increasing the etching factor. The azole compound may include one or more of imidazole, triazole, and tetrazole, but is not limited thereto.

For example, the azole compound may include one or more of 5-aminotetrazole, 3-amino-1,2,4-triazole, 4-amino-4H-1,2,4-triazole, benzotriazole, imidazole, indole, purine, pyrazole, pyridine, pyrimidine, pyrrole, pyrrolidine, and pyrroline, but is not limited thereto.

In the case in which the etchant composition contains the azole compound, a concentration of the azole compound may be 0.001 g/L to 5 g/L based on the aqueous etchant. In the case in which the concentration of the azole compound is less than 0.001 g/L, an addition effect of the azole compound may not be exhibited, and in the case in which the concentration is more than 5 g/L, at the time of etching the metal layer, the etching rate may be decreased, and an etching reaction may be suppressed, such that a short-circuit may occur in the finally formed circuit pattern.

The etchant composition may selectively further contain an organic material including one or more of ethylene glycol, polyethylene glycol, glycerin, polyethylene oxide, polyoxyalkylene glycol, and polyether. The organic material may suppress the side etching to promote the anisotropic etching. Preferably, the organic material may be contained at a concentration of 0.001 g/L to 5 g/L based on the aqueous etchant.

The etchant composition according to an exemplary embodiment of the present disclosure may selectively further contain an additive including one or more of a surfactant, amino acids, pyrimidines, thioureas, amines, alkylpyrrolidones, organic chelates, polyacrylamides, hydrogen peroxide, and persulfate. The additive may suppress the side etching, and it is preferable that the additive is contained at a concentration of 0.01 g/L to 50 g/L based on the aqueous etchant.

Further, the etchant composition may further contain a sequestering agent or a corrosion inhibitor.

Thereafter, a method for manufacturing a circuit pattern according to another exemplary embodiment of the present disclosure will be described.

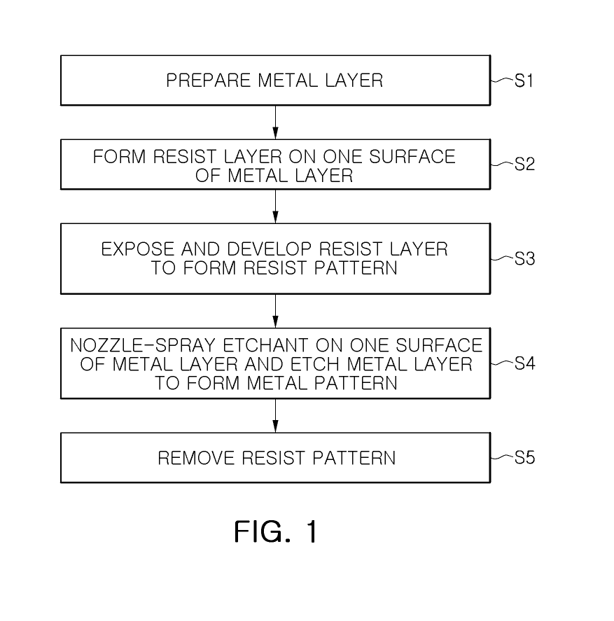

FIG. 1 is a flow chart showing a method for manufacturing a circuit pattern according to an exemplary embodiment of the present disclosure.

Referring to FIG. 1, the method for manufacturing a circuit pattern according to an exemplary embodiment of the present disclosure may include: preparing a metal layer (S1); forming a resist layer on one surface of the metal layer (S2), exposing and developing the resist layer to form a resist pattern (S3); nozzle-spraying an etchant on one surface of the metal layer and etching the metal layer to form a metal pattern (S4); and removing the resist pattern (S5).

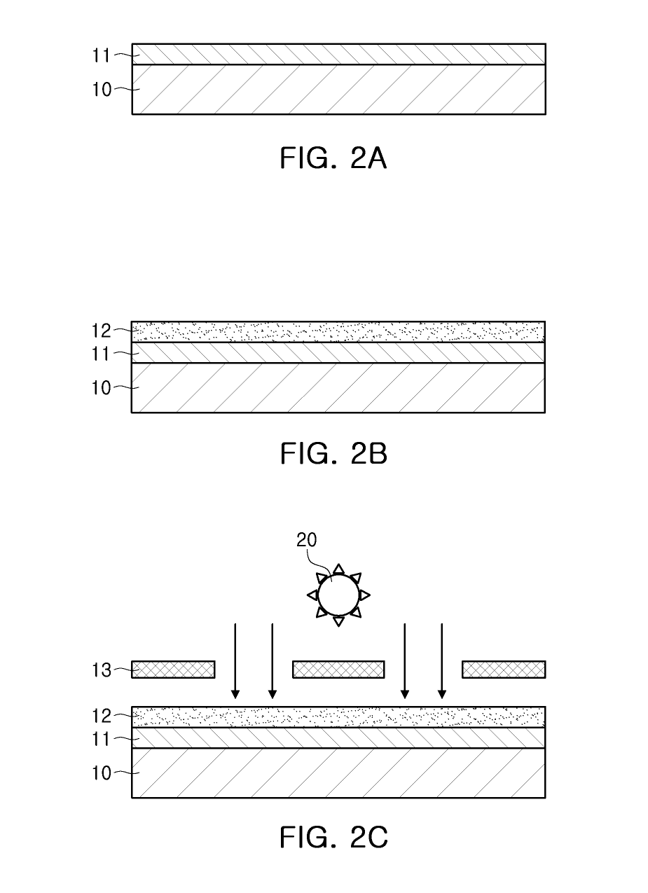

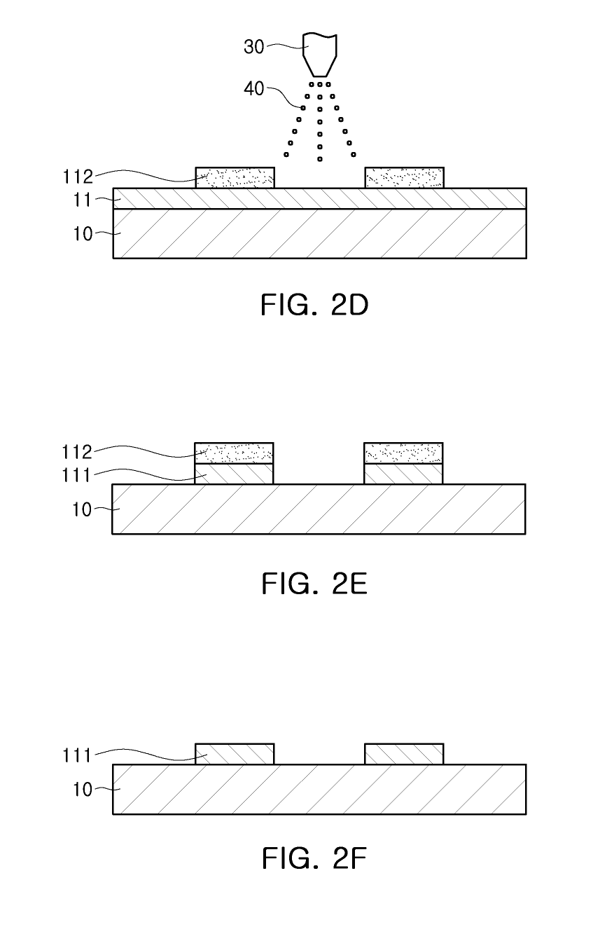

FIGS. 2A through 2F show each of the steps of the method for manufacturing a circuit pattern according to an exemplary embodiment of the present disclosure.

Referring to FIGS. 2A through 2F, first, a metal layer 11, which is a material to be etched, may be prepared on a base board 10 (FIG. 2A), and the metal layer 11 may be prepared on one surface or both surfaces of the base board 10. Then, a resist layer 12 may be formed on one surface of the metal layer 11 (FIG. 2B). Next, the resist layer 12 may be exposed and developed, thereby forming a resist pattern (FIG. 2C). The exposure of the resist layer 12 may be performed by irradiating light from a light source 20 through an exposure mask 13. Thereafter, the resist layer photosensitized by exposure may be developed using a developer, thereby forming a resist pattern 112 (FIG. 2D).

Next, the metal layer 11 including the resist pattern 112 formed thereon may be selectively etched using an etchant (FIG. 2E). The etchant 40 may be sprayed using a nozzle 30, and the sprayed etchant may selectively etch an exposed region of the metal layer since the resist pattern 112 is not disposed thereon, such that a metal pattern 111, which is a circuit pattern, may be formed.

After forming the metal pattern 111, the resist pattern 112 may be removed (FIG. 2F).

The etchant may contain 100 parts by weight of an aqueous etchant containing an oxidant, an acid additive, and water; and 5 to 40 parts by weight of an organic solvent having a viscosity lower than that of water.

A preferable viscosity of the organic solvent may be 0.8 cP or less, and the organic solvent may include, for example, one or more of acetonitrile, nitroethane, methylethylketone, and ethylacetate. The organic solvent may have a boiling point of 50° C. or more, more preferably 70° C. or more.

The etchant may be the above-mentioned etchant composition according to an exemplary embodiment of the present disclosure, and in the present disclosure, in order to avoid an overlapped description, a detailed description thereof will be omitted.

An etching factor of the metal pattern formed by the method for manufacturing a circuit pattern according to an exemplary embodiment of the present disclosure may be 4 or more.

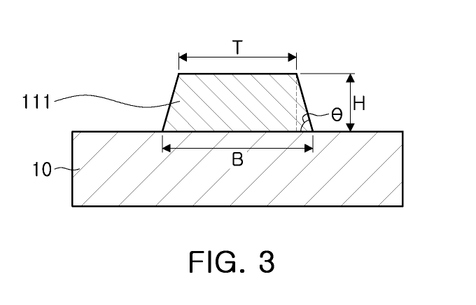

FIG. 3 is a schematic cross-sectional view of a metal pattern illustrating an etching factor.

Referring to FIG. 3, when a width of an upper surface of the metal pattern is defined as T, a width of a lower surface of the metal pattern is defined as B, and a height of the metal pattern is defined as H, the etching factor (E.F) of the metal pattern may be defined as 2×H/(B−T). Alternatively, when an angle between the lower surface of the metal pattern and a side surface thereof is defined as θ, the etching factor (E.F) may be defined as tan θ.

As described above, since the etchant has a low viscosity and surface tension, when the etchant is sprayed from the nozzle, the etchant may be sprayed in small sized etchant particles state. Therefore, the anisotropic etching by hitting in a vertical direction may be increased, such that a ratio of the side etching may be decreased, and high linearity of the formed metal pattern may be implemented.

### Experimental Example 1

The following Table 1 shows results obtained by measuring viscosities of etchants according to the kind of organic solvents contained in etchant compositions and etching factors of metal patterns formed using the etchant compositions.

First, a resist was applied and dried onto a printed circuit board (PCB) base material (100 mm×100 mm) including a copper metal layer having a thickness of 12 μm, followed by exposure, development, and washing, thereby forming a resist pattern having a width of 15 μm. An interval between resist patterns adjacent to each other in the resist pattern was 15 μm.

Next, etchant compositions shown in the following Table 1 were prepared.

Sample 1, which was an aqueous etchant that did not contain an organic solvent, contained copper chloride (CuCl₂), hydrochloric acid (HCl), and residual water as a solvent. In the aqueous etchant, copper chloride was contained at a concentration of 150 g/L, hydrochloric acid was contained at a concentration of 50 g/L, and water (deionized water) was used as a solvent. Hereinafter, an aqueous etchant of sample 1 will be referred to as a first aqueous etchant.

Samples 2 to 6 were Inventive Examples further containing an organic solvent in addition to the first aqueous etchant. In detail, sample 2 contained 20 parts by weight of acetonitrile as the organic solvent based on 100 parts by weight of the first aqueous etchant, sample 3 contained 20 parts by weight of nitroethane as the organic solvent based on 100 parts by weight of the first aqueous etchant, sample 4 contained 20 parts by weight of methylethylketone as the organic solvent based on 100 parts by weight of the first aqueous etchant, and sample 5 contained 20 parts by weight of ethylacetate as the organic solvent based on 100 parts by weight of the first aqueous etchant.

Sample 6 contained 100 parts by weight of a second aqueous etchant containing copper chloride (150 g/L), hydrochloric acid (50 g/L), benzotriazole (1 g/L), polyethylene glycol (1 g/L), and residual water as a solvent and 20 parts by weight of acetonitrile as the organic solvent.

The etching of the metal layer was performed by spraying the prepared etchant composition under a pressure of 0.2 MPa using a spray nozzle. After the etching was completed, the metal pattern (circuit pattern) was obtained by removing the resist pattern, and the viscosity and etching factor (E.F) of each of the samples were measured, thereby comparing degrees of vertical anisotropic etching.

TABLE 1

| | | Viscosity | Etching |
|---|---|---|---|
| Sample | Etchant Composition | of Etchant | Factor |
| 1* | First Aqueous Etchant (CuCl₂ (150 g/L), | 0.99 cP | 2.7 |
| | HCl (50 g/L), and water) | | |
| 2 | First Aqueous Etchant (100 Parts by | 0.84 cP | 5.1 |
| | Weight) + Acetonitrile (20 Parts | | |
| | by Weight) | | |
| 3 | First Aqueous Etchant (100 Parts by | 0.90 cP | 4.6 |
| | Weight) + nitroethane (20 Parts | | |
| | by Weight) | | |
| 4 | First Aqueous Etchant (100 Parts by | 0.85 cP | 4.9 |
| | Weight) + methylethylketone | | |
| | (20 Parts by Weight) | | |
| 5 | First Aqueous Etchant (100 Parts by | 0.86 cP | 4.8 |
| | Weight) + ethylacetate (20 Parts | | |
| | by Weight) | | |
| 6 | Second Aqueous Etchant (CuCl₂ | 0.84 cP | 5.5 |
| | (150 g/L), HCl (50 g/L), benzotriazole | | |
| | (1 g/L), polyethylene glycol (1 g/L), | | |
| | and water, 100 Parts by Weight) + | | |
| | Acetonitrile (20 Parts by Weight) | | |

*Comparative Example

Referring to Table 1, it may be confirmed that in the cases of samples 2 to 6 containing the organic solvent having a viscosity of 0.8 cP or less and a boiling point 70° C. or more, the etching factors (E.F) were increased about 1.7 times or more than that of sample 1. In addition, it may be confirmed that in sample 6 using the second aqueous etchant further containing benzotriazole (1 g/L) and polyethylene glycol (1 g/L) suppressing the side etching, the etching factor was further improved.

Therefore, at the time of etching the metal layer by nozzle-spray of the etchant, in the case of using the etchant compositions of samples 2 to 6 rather than sample 1, a particle size of the sprayed etchant may be decreased, such that the metal pattern having a high etching factor may be formed.

### Experimental Example 2

The following Table 2 shows results obtained by measuring viscosities of etchants according to the content of organic solvents contained in etchant compositions and etching factors of metal patterns formed using the etchant compositions.

As in Experimental Example 1, a resist was applied and dried onto a PCB base material (100 mm×100 mm) including a copper metal layer having a thickness of 12 μm, followed by exposure, development, and washing, thereby forming a resist pattern having a width of 15 μm. An interval between resist patterns adjacent to each other in the resist pattern was 15 μm.

Next, etchant compositions shown in the following Table 2 were prepared.

Sample 7, which was an aqueous etchant that did not contain an organic solvent, contained copper chloride (CuCl₂), hydrochloric acid (HCl), benzotriazole, polyethylene glycol, and water (deionized water) as a solvent. In the aqueous etchant, copper chloride was contained at a concentration of 150 g/L, hydrochloric acid was contained at a concentration of 50 g/L, benzotriazole was contained at a concentration of 1 g/L, and polyethylene glycol was contained at a concentration of 1 g/L. Hereinafter, sample 7 will be referred to as a third aqueous etchant.

Samples 8 to 13 further contained an organic solvent at a content shown in Table 2 based on 100 parts by weight of the third aqueous etchant.

The etching of the metal layer was performed by spraying the etchant composition prepared as shown in Table 2 under a pressure of 0.2 MPa using a spray nozzle. After the etching was completed, the metal pattern (circuit pattern) was obtained by removing the resist pattern, and the viscosity and etching factor (E.F) of each of the samples were measured, thereby comparing degrees of vertical anisotropic etching.

Acetonitrile has a viscosity of about 0.37 cP and a boiling point of about 82° C. or more.

TABLE 2

| | | Viscosity | Etching |
|---|---|---|---|
| Sample | Etchant Composition | of Etchant | Factor |
| 7* | Third Aqueous Etchant (CuCl₂ (150 g/L), | 0.99 cP | 3.3 |
| | HCl (50 g/L), benzotriazole (1 g/L), | | |
| | polyethylene glycol (1 g/L), and water) | | |
| 8 | Third Aqueous Etchant (100 Parts by | 0.93 cP | 4.3 |
| | Weight) + Acetonitrile (5 Parts | | |
| | by Weight) | | |
| 9 | Third Aqueous Etchant (100 Parts by | 0.90 cP | 4.8 |
| | Weight) + Acetonitrile (10 Parts | | |
| | by Weight) | | |
| 10 | Third Aqueous Etchant (100 Parts by | 0.84 cP | 5.5 |
| | Weight) + Acetonitrile (20 Parts | | |
| | by Weight) | | |
| 11 | Third Aqueous Etchant (100 Parts by | 0.78 cP | 5.1 |
| | Weight) + Acetonitrile (30 Parts | | |
| | by Weight) | | |
| 12 | Third Aqueous Etchant (100 Parts by | 0.73 cP | 4.6 |
| | Weight) + Acetonitrile (40 Parts | | |
| | by Weight) | | |
| 13 | Third Aqueous Etchant (100 Parts by | 0.66 cP | 3.6 |
| | Weight) + Acetonitrile (50 Parts | | |
| | by Weight) | | |

*Comparative Example

Referring to Table 2, it may be confirmed that in the case of sample 7 in which the content of acetonitrile was less than 5 parts by weight based on 100 parts by weight of the third aqueous etchant, the etching factor was less than 4, but in the cases of samples 8 to 12 in which the content of acetonitrile was 5 to 40 parts by weight based on 100 parts by weight of the third aqueous etchant, the etching factor was high (4 or more). In addition, referring to sample 13, it may be confirmed that in the case in which the content of acetonitrile, which is an organic solvent, was more than 40 parts by weight, the etching factor was decreased again, such that the measured etching factor was less than 4.

As set forth above, according to exemplary embodiments of the present disclosure, the etchant composition capable of manufacturing the metal pattern having a high etching factor and the method for manufacturing a circuit pattern using the etchant composition may be provided.

While exemplary embodiments have been shown and described above, it will be apparent to those skilled in the art that modifications and variations could be made without departing from the spirit and scope of the present disclosure as defined by the appended claims.

What is claimed is:

1. An etchant composition comprising:
100 parts by weight of an aqueous etchant containing an oxidant, an acid additive, and water; and
5 to 40 parts by weight of an organic solvent having a viscosity lower than that of water.

2. The etchant composition of claim 1, wherein the organic solvent has a viscosity of 0.8 cP or less.

3. The etchant composition of claim 1, wherein a concentration of the oxidant contained in the aqueous etchant is 50 g/L to 200 g/L based on the aqueous etchant.

4. The etchant composition of claim 1, wherein a concentration of the acid additive contained in the aqueous etchant is 0.1 mol/L to 5 mol/L based on the aqueous etchant.

5. The etchant composition of claim 1, wherein the organic solvent has a boiling point of 70° C. or more.

6. The etchant composition of claim 1, wherein the organic solvent includes one or more of acetonitrile, nitroethane, methylethylketone, and ethylacetate.

7. The etchant composition of claim 1, wherein the oxidant includes one or more of copper(II) chloride, copper(II) bromide, copper(II) sulfate, copper(II) hydroxide, copper(II) acetate, iron(II) chloride, iron(II) bromide, iron(II) iodide, iron(II) sulfate, iron(II) nitrate, and iron(II) acetate.

8. The etchant composition of claim 1, wherein the acid additive includes one or more of sulfuric acid, hydrochloric acid, nitric acid, phosphoric acid, formic acid, acetic acid, maleic acid, benzoic acid, glycolic acid, and sulfonic acid.

9. The etchant composition of claim 1, wherein the aqueous etchant further contains one or more of hydrogen peroxide (H₂O₂) and sodium chlorate (NaClO₃).

10. A method for manufacturing a circuit pattern, the method comprising:
preparing a metal layer;
forming a resist layer on one surface of the metal layer;
exposing and developing the resist layer to forma resist pattern;
nozzle-spraying an etchant on one surface of the metal layer and etching the metal layer to form a metal pattern; and
removing the resist pattern,
wherein the etchant contains 100 parts by weight of an aqueous etchant containing an oxidant, an acid additive, and water; and 5 to 40 parts by weight of an organic solvent having a viscosity lower than that of water.

11. The method of claim 10, wherein the organic solvent has a viscosity of 0.8 cP or less.

12. The method of claim 10, wherein an etching factor of the metal pattern formed by etching the metal layer is 4 or more.

13. The method of claim 10, wherein a concentration of the oxidant contained in the aqueous etchant is 50 g/L to 200 g/L based on the aqueous etchant.

14. The method of claim 10, wherein a concentration of the acid additive contained in the aqueous etchant is 0.1 mol/L to 5 mol/L based on the aqueous etchant.

15. The method of claim 10, wherein the organic solvent has a boiling point of 70° C. or more.

16. The method of claim 10, wherein the organic solvent includes one or more of acetonitrile, nitroethane, methylethylketone, and ethylacetate.
